(19) United States
(12) Patent Application Publication
(10) Pub. No.: US 2010/0307806 A1
(43) Pub. Date: Dec. 9, 2010

(54) PRINTED CIRCUIT BOARD

(75) Inventors: YUNG-CHIEH CHEN, Tu-Cheng (TW); CHIEN-HUNG LIU, Tu-Cheng (TW); SHOU-KUO HSU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/504,798

(22) Filed: Jul. 17, 2009

(30) Foreign Application Priority Data
Jun. 5, 2009 (CN) 200910302966.X

(51) Int. Cl. H05K 1/11

(52) U.S. Cl. 174/261

(57) ABSTRACT

A printed circuit board includes a signal layer and a power layer. A differential pair with two transmission lines is set on the signal layer. A cross-trench portion is formed in the power layer. A first width of each transmission line which is not located above the cross-trench portion is less than a second width of the transmission line which is located above the cross-trench portion. A first distance between the two transmission lines which are not located above the cross-trench portion is greater than a second distance between the two transmission lines which are located above the cross-trench portion.

### BACKGROUND

1. Technical Field

The present disclosure relates to a printed circuit board.

2. Description of Related Art

High-speed digital circuits are generally constructed on a multi-layer circuit board which includes multiple circuit layers. In the multi-layer circuit board, each signal line is associated with a copper-based reference plane which is used to provide a looped path that can ensure signal fidelity and prevent electromagnetic interference (EMI) effects. In this multi-layer design, however, it is often required to separate the power layer of the multi-layer circuit board with different system voltages applied to the other layers, for example a 3.3 V and a 5.0 V. Between the different system voltages, a cross-trench portion is formed.

Under this condition, bounce noise would easily occur when the signal lines pass through the across-trench portion of the power layer, thereby resulting in EMI effects that would degrade the fidelity of the high-speed digital signal transmitting therethrough. As a result, users may position a capacitor near the cross-trench portion to reduce the bounce noise. However, adding the capacitor is inconvenient because adds an additional component for a limited size multi-layer circuit board.

### BRIEF DESCRIPTION OF THE DRAWINGS

FIG. 1 is an isometric view of an exemplary embodiment of a printed circuit board.

FIG. 2 is a top plan view of the printed circuit board of FIG. 1.

FIG. 3 is a graph of the capacity of a printed circuit board showing frequencies of a signal transmitted on transmission lines and the capacity of the transmission lines on a printed circuit board for signal transmission.

### DETAILED DESCRIPTION

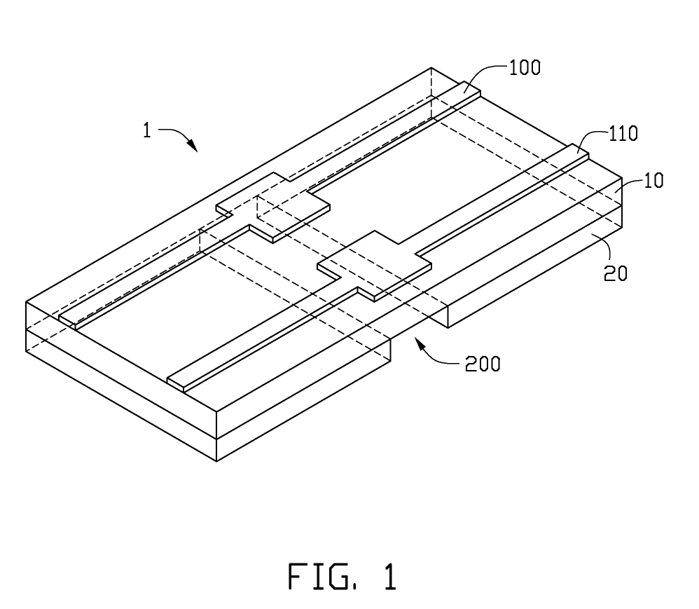

Referring to FIG. 1, an exemplary embodiment of a printed circuit board 1 includes a signal layer 10 and a power layer 20.

A differential pair, which includes a first transmission line 100 and a second transmission line 110, is set on the signal layer 10. In order to separate different system voltages, such as 3.3 V and 5 V, on the power layer 20, a cross-trench 200 is formed on the power layer 20.

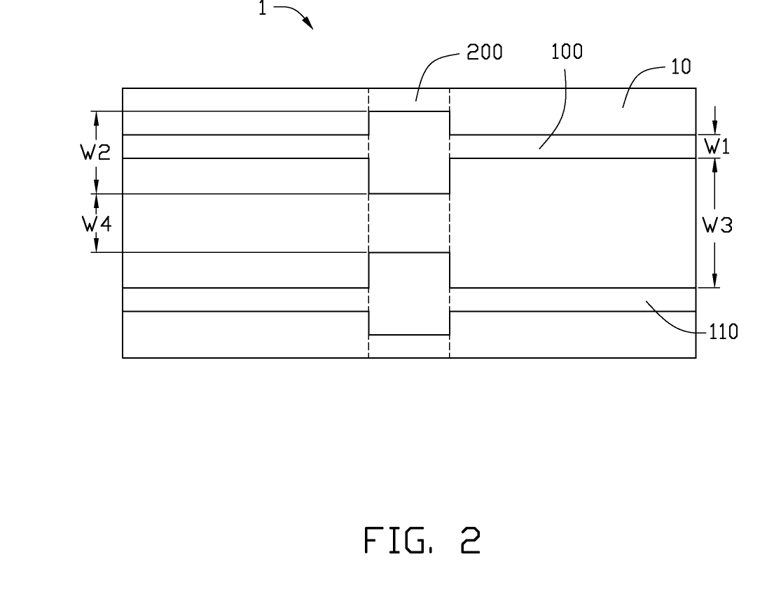

Referring to FIG. 2, a first width of the first transmission line 100 which is not located on the cross-trench 200 is W1, and a second width which is located on the cross-trench 200 is W2. W1 and W2 are greater than zero, and W1 is less than W2. The second transmission line 110 is the same as the first transmission line 100. In the embodiment, W1 is about equal to 4 mils (1 mil= 1/1000 inch), W2 is about equal to 5.5 mils.

A first distance between the first transmission line 100 and the second transmission line 110 which are not located on the cross-trench 200 is W3, and a second distance between the first and second transmission lines 100, 110 which are located on the cross-trench 200 is W4. W3 and W4 are greater than zero, and W3 is greater than W4. In the embodiment, W3 is about to equal to 6 mils, and W4 is about equal to 4 mils.

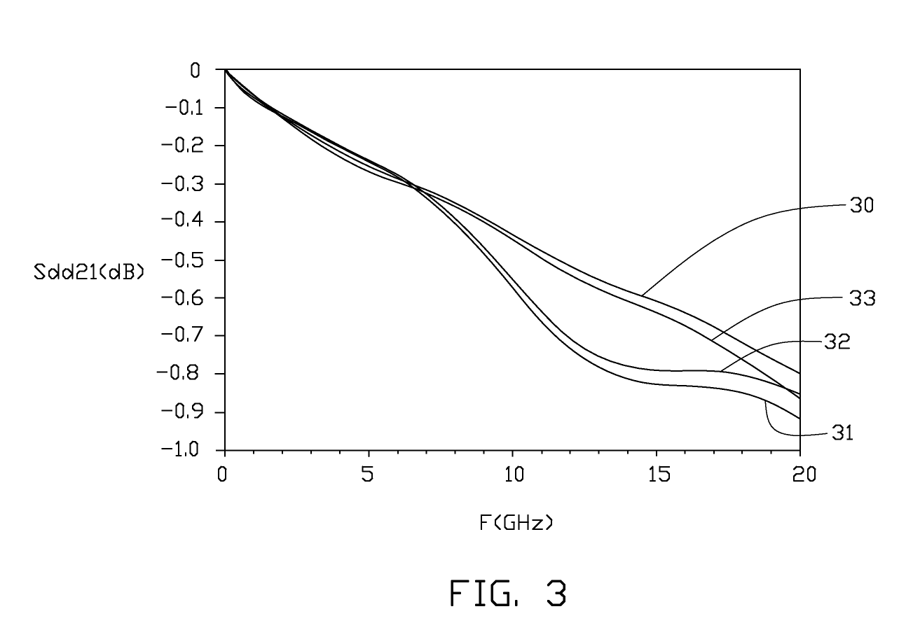

It can be understood that the capacity of the transmission lines on the printed circuit board 1 denotes a ratio between signal strength on a sending end and signal strength on a receiving end. The signal is transmitted from the sending end to the receiving end. FIG. 3 is a graph of the capacity of a printed circuit board showing frequencies of a signal transmitted on transmission lines and the capacity of the transmission lines on a printed circuit board for signal transmission. In the illustrated embodiment, the horizontal axis of the coordinate axis denotes frequencies of a signal transmitted on transmission lines, and the vertical axis of the coordinate axis denotes the capacity of the transmission lines on a printed circuit board for signal transmission. FIG. 3 shows four curves to denote four different capacities corresponding to four different structures. It may be understood that the capacity of the transmission lines on the printed circuit board for signal transmission is better when the vertical coordinate of a curve is closer to zero.

A first curve 30 denotes the capacity of a first printed circuit board without a cross-trench portion for signal transmission, a second curve 31 denotes the capacity of a second printed circuit board with a cross-trench portion but without a capacitor for signal transmission, a third curve 32 denotes the capacity of a third printed circuit board with a cross-trench portion and a capacitor located on the printed circuit board for signal transmission, and a fourth curve 33 denotes the capacity of the printed circuit board 1 for signal transmission.

As shown, because the first printed circuit board has no cross-trench portion on its power layer, there is no bounce noise for signal transmission in the transmission lines on the signal layer of the first printed circuit board. As a result, the capacity of the first printed circuit board without a cross-trench portion for signal transmission is the best. Moreover, because the second printed circuit board has a cross-trench portion on its power layer, and there is no capacitor to reduce the bounce noise for signal transmission in the transmission lines on the signal layer of the first printed circuit board, the capacity of the printed circuit board with a cross-trench portion while without a capacitor for signal transmission is the worst. In addition, for the third curve 32, the capacity of the printed circuit board with a cross-trench portion and a capacitor for signal transmission is better than the capacity of the printed circuit board with a cross-trench portion while without a capacitor for signal transmission, especially when the frequency of the signal is high. For the fourth curve 33, the capacity of the printed circuit board 1 for signal transmission is better than the capacity of the printed circuit board with a cross-trench portion and a capacitor for signal transmission, especially when the frequency of signal is around 14 GHz.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising:
a signal layer, wherein a differential pair is set on the signal layer, the differential pair comprising two transmission lines; and
a power layer comprising a cross-trench portion formed in the power layer;
wherein a first width of each of the two transmission lines which is not located above the cross-trench portion is less than a second width of the transmission line which is located above the cross-trench portion, and a first distance between the two transmission lines which are not located above the cross-trench portion is greater than a second distance between the two transmission lines which are located above the cross-trench portion.

2. The printed circuit board of claim 1, wherein the first width is about equal to 4 mils.

3. The printed circuit board of claim 1, wherein the second width is about equal to 5.5 mils.

4. The printed circuit board of claim 1, wherein the first distance is about equal to 6 mils.

5. The printed circuit board of claim 1, wherein the second distance is about equal to 4 mils.
